(19) United States
(12) Patent Application Publication
(10) Pub. No.: US 2026/0156904 A1
(43) Pub. Date: Jun. 4, 2026

(54) METHOD OF REPAIRING INTEGRATED CIRCUIT

(71) Applicants: Semiconductor Technology Innovation Center (Beijing) Corporation, Beijing (CN); INSTITUTE OF MICROELECTRONICS, CHINESE ACADEMY OF SCIENCES, Beijing (CN)

(72) Inventors: Hong YANG, Beijing (CN); Mingyang SUN, Beijing (CN); Qianqian LIU, Beijing (CN); Weihai BU, Beijing (CN); Xiaolei WANG, Beijing (CN); Jun LUO, Beijing (CN); Yongqin WU, Beijing (CN); Wenwu WANG, Beijing (CN)

(21) Appl. No.: 19/270,028

(22) Filed: Jul. 15, 2025

(30) Foreign Application Priority Data
Dec. 3, 2024 (CN) 202411766369.3

(51) Int. Cl. H01L 21/77; G01R 31/28; G11C 29/50; H03K 17/687

(52) U.S. Cl. CPC H10D 84/01; G01R 31/2884; G11C 29/50004; H03K 17/687

(57) ABSTRACT

The present disclosure provides a method of repairing an integrated circuit, which relates to a field of integrated circuit technology. The method of repairing the integrated circuit includes: providing an integrated circuit to be repaired; acquiring a first performance-related parameter and a performance degradation-related parameter of the integrated circuit to be repaired, and establishing a circuit aging model; simulating the integrated circuit to be repaired, and determining the transistor to be repaired in the integrated circuit to be repaired and its first pre-failure duration; acquiring a second performance-related parameter of the transistor to be repaired; determining a repair parameter corresponding to the transistor to be repaired; and repairing the transistor to be repaired according to the first pre-failure duration and the repair parameter by using a gate-induced drain leakage current repair method.

### CROSS REFERENCE TO RELATED APPLICATION

This application claims priority to Chinese Patent Application No. 202411766369.3, filed on Dec. 3, 2024, the entire content of which is incorporated herein in its entirety by reference.

### TECHNICAL FIELD

The present disclosure relates to a field of integrated circuit technology, and in particular to a method of repairing an integrated circuit.

### BACKGROUND

An integrated circuit may degrade in performance after a long-term operation, thus may fail to operate properly within a designed lifespan. In an overall design of an integrated circuit, it is needed to perform an optimization design in combination with post-production testing in order to extend the lifespan of the integrated circuit.

In the related art, to repair aging of an integrated circuit, it is typical to perform a lifespan test on the integrated circuit after a manufacture is completed, determine a failure cause of the integrated circuit through statistics based on aging situations of integrated circuits during actual applications, and then optimize device parameters and structural parameters of the integrated circuit to extend its lifespan. Such a repair method requires adjusting parameters through an actual lifespan testing in combination with the actual aging situation after production, which is a redesign of the integrated circuit. During a process of testing and modifying parameters, a large amount of time is consumed and a large number of integrated circuits with short lifespans are produced, resulting in low repair efficiency and lacking real-time performance. Furthermore, due to various limitations of the parameter adjustment method, it is difficult to accurately and effectively extend the lifespan of the integrated circuit, thus affecting the performance of the integrated circuit during a long-term operation.

### SUMMARY

An objective of the present disclosure is to provide a method of repairing an integrated circuit, which is used to improve the real-time performance, repair accuracy and repair effect in repairing aging of the integrated circuit, thereby improving a performance of the integrated circuit during a long-term operation.

The present disclosure provides a technical solution as follows. First, an integrated circuit to be repaired is provided; then a first performance-related parameter and a performance degradation-related parameter of the integrated circuit to be repaired are acquired, and a circuit aging model is established according to the first performance-related parameter. Then by simulating the integrated circuit to be repaired, a simulated performance-related parameter is obtained. Subsequently, a transistor to be repaired in the integrated circuit to be repaired and a first pre-failure duration is determined according to the circuit aging model, the simulated performance-related parameter and the performance degradation-related parameter. Then a second performance-related parameter of the transistor to be repaired is determined. A repair parameter corresponding to the transistor to be repaired is calculated according to the second performance-related parameter, the simulated performance-related parameter and the performance degradation-related parameter. Finally, the transistor to be repaired is repaired according to the first pre-failure duration and the repair parameter by using a gate-induced drain leakage current repair method.

When the above-mentioned technical solution is adopted, before repairing the integrated circuit to be repaired, the first performance-related parameter and the performance degradation-related parameter of the integrated circuit to be repaired are acquired in advance. The first performance-related parameter may characterize an operating state of the integrated circuit to be repaired and corresponding operating parameters in the operating state. Based on this, a circuit aging model for a single transistor included in the integrated circuit to be repaired is established according to the first performance-related parameter, so as to perform a targeted assessment of the aging situation of the integrated circuit to be repaired, thus accurately understanding the performance degradation situation of each transistor in the integrated circuit to be repaired and improving a simulation accuracy. In addition, the performance degradation-related parameter may be used as a determination threshold criterion for the integrated circuit to be repaired. Then, the obtained simulated performance-related parameter, that is, a simulation result, is compared with the performance degradation-related parameter to determine the aging situation and the first pre-failure duration of each transistor in the integrated circuit to be repaired. If the simulated performance-related parameter of a particular transistor were to meet a degradation criterion in the performance degradation-related parameter, that transistor could be determined as a transistor to be repaired, and the transistor to be repaired may be repaired in a subsequent repair process. Secondly, the ratio between the simulated performance-related parameter and the degradation-related parameter is used as a parameter to evaluate the degradation situation of the transistor to be repaired, so as to facilitate subsequent repair of the transistor to be repaired. The first pre-failure duration refers to a duration after which the simulated performance-related parameter of the transistor to be repaired is considered to meet the degradation criterion in the performance degradation-related parameter. After that, the second performance-related parameter of the transistor to be repaired is acquired, which serves as a basic device parameter of the transistor to be repaired and will be used as a basis for determining the specific means of the subsequent repair method. Then, the degradation situation of the transistor to be repaired is obtained according to the second performance-related parameter, the simulated performance-related parameter and the performance degradation-related parameter. Combining the degradation situation of the transistor to be repaired and the basic device parameter of the transistor to be repaired, the repair parameter for repairing the transistor to be repaired may be determined. Finally, the transistor to be repaired may be repaired according to the first pre-failure duration and the repair parameter by using a gate-induced drain leakage current repair method. In contrast to the related art, which relies on thermal annealing to repair an aged transistor to be repaired and requires annealing the entire integrated circuit to be repaired, thereby inevitably interrupting a normal operation of a system using the integrated circuit to be repaired and incurring lengthy repair time, the present disclosure is to repair the transistor to be repaired by using a gate-induced drain leakage current repair method, so that the integrated circuit to be repaired may be repaired without interrupting a normal operation of the system using the integrated circuit to be repaired, and the repair time may be significantly reduced. Moreover, the repair method provided in the present disclosure does not involve adjusting the device parameter of the integrated circuit and then remanufacturing the integrated circuit, thus solving the problems of low efficiency and low real-time performance of the indirect repair method in the related art that requires post-production testing of the integrated circuit to adjust the parameter of the integrated circuit for lifespan extension. Furthermore, by directly repairing the transistor to be repaired, it is possible to use relatively conservative repair parameters to solve the problems of low repair accuracy and poor repair effect caused by low simulation precision, thereby improving the performance of the integrated circuit to be repaired during a long-term operation.

As a possible implementation solution, the first performance-related parameter includes a designed operating temperature, a designed maximum voltage stress, a designed operating duration, a designed threshold voltage, a designed saturation drain current, and a designed circuit turn-on delay time.

When the above-mentioned technical solution is adopted, the first performance-related parameter, as the parameter for enabling a normal operation of the integrated circuit to be repaired, is used to establish a circuit aging model, so that a simulation may be performed using the circuit aging model. In this case, the designed operating temperature, the designed maximum voltage stress and the designed operating duration may comprehensively represent the operating state of the integrated circuit to be repaired, and the integrated circuit to be repaired needs to operate at the designed operating temperature for at least the designed operating duration; the designed threshold voltage, the designed saturation drain current and the designed circuit turn-on delay time may comprehensively characterize various parameters required for the integrated circuit to be repaired in the operating state, so that the circuit aging model established based on the first performance-related parameter may accurately reflect the actual situation of the integrated circuit to be repaired, thereby enhancing the accuracy of the simulation result and improving the repair effect of the repair method provided in the present disclosure.

As a possible implementation solution, the performance degradation-related parameter includes a circuit type, a degraded threshold voltage, a degraded saturation drain current, and a degraded circuit turn-on delay time; and the circuit type includes a memory, an arithmetic unit, or an amplifier.

When the above-mentioned technical solution is adopted, the performance degradation-related parameter is used as the criterion for determining the aging situation of the integrated circuit to be repaired. The criterion for determining the aging situation of the integrated circuit to be repaired based on the four parameters including the circuit type, the degraded threshold voltage, the degraded saturation drain current and the degraded circuit turn-on delay time may comprehensively characterize various parameters required for the integrated circuit to be repaired in the operating state, so that a result of determining the integrated circuit to be repaired using the performance degradation-related parameter is more effective, and the transistor to be repaired may be determined accurately, thereby improving the repair effect of the repair method provided in the present disclosure.

As a possible implementation solution, when the integrated circuit to be repaired is a memory, the difference between the degraded threshold voltage and the designed threshold voltage is greater than or equal to 30 mV, the degradation ratio between the degraded saturation drain current and the designed saturation drain current is greater than or equal to 15%, and the degradation ratio between the designed circuit turn-on delay time and the degraded circuit turn-on delay time is greater than or equal to 30%. When the integrated circuit to be repaired is an arithmetic unit, the difference between the degraded threshold voltage and the designed threshold voltage is greater than or equal to 30 mV, and the degradation ratio between the degraded saturation drain current and the designed saturation drain current is greater than or equal to 15%, while the degradation ratio between the designed circuit turn-on delay time and the degraded circuit turn-on delay time is greater than or equal to 30%. When the integrated circuit to be repaired is an amplifier, the difference between the degraded threshold voltage and the designed threshold voltage is greater than or equal to 30 mV, the degradation ratio between the degraded saturation drain current and the designed saturation drain current is greater than or equal to 15%, and the degradation ratio between the designed circuit turn-on delay time and the degraded circuit turn-on delay time is greater than or equal to 30%.

When the above-mentioned technical solution is adopted, since different types of integrated circuits to be repaired have different uses and may have the same or different failure criteria for different parameters, appropriate failure criteria are selected for different parameters according to operating characteristics of different types of integrated circuits to be repaired, thereby improving pertinence of the repair method provided in the present disclosure and ultimately improving the effect of the method of repairing the integrated circuit provided in the present disclosure.

As a possible implementation solution, the second performance-related parameter includes a decrease amount of threshold voltage, a subthreshold swing, a transconductance, an electric field strength distribution, a decrease amount of saturation drain current, an overlapping length between gate region and drain region, and a gate dielectric layer thickness.

When the above-mentioned technical solution is adopted, the second performance-related parameter is used as a device parameter of the transistor to be repaired. In subsequent repair of the transistor to be repaired, the second performance-related parameter is used to repair the device aging of the transistor to be repaired. Common device aging, such as hot carrier degradation (HCD), originating from heating and subsequent carrier injection into a gate oxide layer, leads to a formation of local and non-uniform interface states and oxide charge accumulation near a drain junction of the transistor. The resulting defects may cause threshold voltage drift, transconductance degradation, drain current reduction, etc., ultimately causing device failure. Furthermore, a lateral electric field near the drain junction causes carrier heating and avalanche, the lateral electric field affects the carrier injection into the gate oxide layer, and the electric field distribution in the transistor may also have a significant impact on the hot carrier degradation of the transistor. In this case, specific parameters such as the decrease amount of threshold voltage, the subthreshold swing, the transconductance, the electric field strength distribution, the decrease amount of saturation drain current, the overlapping length between gate region and drain region, and the gate dielectric layer thickness used as device parameters of the transistor to be repaired may effectively represent the hot carrier degradation of the transistor to be repaired, thereby facilitating the subsequent accurate calculation of the first pre-failure duration and the repair parameter, and improving the repair effect of the repair method provided in the present disclosure.

As a possible implementation solution, a relational expression of the circuit aging model includes:

$${V}_{th} = A * {e}^{\frac{- 1}{kT}} * {V}_{g} * b * {t}^{n}$$

where Vₜₕ represents the threshold voltage, A represents a first threshold voltage degradation parameter, k represents the Boltzmann constant, T represents an operating temperature, V_{g} represents a stress bias voltage, b represents a second threshold voltage degradation parameter, t represents an operating duration, and n is a time exponent.

When the above-mentioned solution is adopted, the establishment of the circuit aging model is to determine a specific value of the parameter. In this case, the threshold voltage in the circuit aging model may effectively characterize the aging situation of the integrated circuit to be repaired by using the above relational expression, making the circuit aging model more accurate and improving the repair effect of the repair method provided in the present disclosure.

As a possible implementation solution, determining a transistor to be repaired in the integrated circuit to be repaired and a first pre-failure duration according to the circuit aging model, the simulated performance-related parameter and the performance degradation-related parameter includes: calculating the first pre-failure duration according to the circuit aging model and the performance degradation-related parameter; and determining the transistor to be repaired according to the first pre-failure duration and the simulated performance-related parameter.

When the above-mentioned solution is adopted, an accurate first pre-failure duration may be obtained. When subsequently repairing the transistor to be repaired based on the first pre-failure duration, it may be ensured that the performance degradation of the transistor to be repaired does not exceed the designed value, thereby ensuring the effectiveness of the repair method provided in the present disclosure.

As a possible implementation solution, the simulated performance-related parameter includes a circuit type, a simulated threshold voltage, a simulated saturation drain current, and a simulated circuit turn-on delay time; and the repair parameter includes a gate-drain voltage and a repair time.

When the above solution is adopted, the simulated performance-related parameter is used as a simulation result of the circuit aging model. The simulated performance-related parameter has the same parameter type as the performance degradation-related parameter. By comparing the simulated performance-related parameter with the performance degradation-related parameter, the aging situation of the integrated circuit to be repaired and the transistor to be repaired in the integrated circuit to be repaired may be determined more effectively. The repair parameter is used as an operating parameter for subsequent repair. Since a gate-induced drain leakage current repair method is adopted for repair in the repair method provided in the present disclosure, obtaining the gate-drain voltage and the repair time used for the repair may further improve the repair effect and ensure that the repair effect meets the design expectations.

As a possible implementation solution, determining a repair parameter corresponding to the transistor to be repaired according to the second performance-related parameter, the simulated performance-related parameter and the performance degradation-related parameter includes: determining the gate-drain voltage and the repair time in the repair parameter according to the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter.

When the above-mentioned solution is adopted, the gate-drain voltage and the repair time in the repair parameter are obtained by combining and analyzing the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter, and they are used to repair the transistor to be repaired. Based on the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter, the gate-drain voltage and the repair time used for repairing the transistor to be repaired may be accurately determined, thereby improving the repair effect of the method of repairing the integrated circuit provided in the present disclosure.

As a possible implementation solution, repairing the transistor to be repaired according to the first pre-failure duration and the repair parameter by using a gate-induced drain leakage current repair method includes: performing an operation of setting a gate electrode, a source electrode and a substrate of the transistor to be repaired to a low level and setting a drain electrode of the transistor to be repaired to a high level to trigger a gate-induced drain leakage current according to the repair parameter after timing reaches the first pre-failure duration; and restarting the timing, and repeatedly performing the operation.

When the above-mentioned solution is adopted, after the timing reaches the first pre-failure duration, the transistor to be repaired is repaired using a gate-induced drain leakage current repair method. The repair method is simple, and the corresponding repair circuit is also simple, which may reduce a design difficulty of the method of repairing the integrated circuit provided in the present disclosure and reduce the design overhead and power consumption overhead on the repair circuit.

As a possible implementation solution, repairing the transistor to be repaired according to the first pre-failure duration and the repair parameter by using a gate-induced drain leakage current repair method includes: performing an operation of: performing a real-time performance test on the transistor to be repaired to obtain a third performance-related parameter after timing reaches the first pre-failure duration, and determining a current performance degradation ratio according to the third performance-related parameter and the performance degradation-related parameter; in a case that the current performance degradation ratio is greater than or equal to a performance degradation threshold, setting a gate electrode, a source electrode and a substrate of the transistor to be repaired to a low level and setting a drain electrode of the transistor to be repaired to a high level to trigger a gate-induced drain leakage current according to the repair parameter; and in a case that the current performance degradation ratio is less than the performance degradation threshold, determining a second pre-failure duration according to the third performance-related parameter and the performance degradation-related parameter; after the timing reaches the second pre-failure duration, setting the gate electrode, the source electrode and the substrate of the transistor to be repaired to a low level and setting the drain electrode of the transistor to be repaired to a high level to trigger a gate-induced drain leakage current according to the repair parameter; and updating the first pre-failure duration according to the second pre-failure duration; and restarting the timing and repeatedly performing the operation.

When the above-mentioned solution is adopted, the second pre-failure duration and the first pre-failure duration have the same starting time; and the performance degradation threshold may be obtained manually according to actual needs, or may be a threshold of the difference between the degraded threshold voltage and the designed threshold voltage, a threshold of the degradation ratio between the degraded saturation drain current and the designed saturation drain current, and a threshold of the degradation ratio between the designed circuit turn-on delay time and the degraded circuit turn-on delay time included in the performance degradation-related parameter. The third performance-related parameter includes the threshold voltage, the saturation drain current and the circuit turn-on delay time of the transistor to be repaired. Determining the current performance degradation ratio according to the third performance-related parameter and the performance degradation-related parameter is to determine the current performance degradation ratio of the threshold voltage, saturation drain current and circuit turn-on delay time of the transistor to be repaired, and determine whether the current performance degradation ratio exceeds the above-mentioned performance degradation threshold included in the performance degradation-related parameter. In this case, the alternative repair method expands the application scope of repairing the integrated circuit provided in the present disclosure. Furthermore, since a real-time performance test is performed on the transistor to be repaired and a third performance-related parameter is obtained before the transistor to be repaired is repaired, and then the current performance degradation ratio is determined according to the third performance-related parameter and the performance degradation-related parameter, the transistor to be repaired may be repaired only when the current performance degradation ratio is greater than or equal to the performance degradation threshold, thereby reducing the number of repairs, avoiding invalid repairs or multiple repairs that may damage the device structure of the transistor to be repaired, and effectively extending the lifespan of the integrated circuit to be repaired.

As a possible implementation solution, repairing the transistor to be repaired according to the first pre-failure duration and the repair parameter by using a gate-induced drain leakage current repair method further includes: repairing, by using a repair circuit, the transistor to be repaired according to the first pre-failure duration and the repair parameter by using the gate-induced drain leakage current repair method, where the repair circuit includes a timer and a repair module, the timer is configured to be triggered at intervals of the first pre-failure duration, and the repair module is connected to at least the gate electrode, the source electrode, the drain electrode and the substrate of the transistor to be repaired; the repair module is configured to: test a performance of the transistor to be repaired to obtain the third performance-related parameter after the timer is triggered, and determine the current performance degradation ratio according to the third performance-related parameter and the performance degradation-related parameter; in the case that the current performance degradation ratio is greater than or equal to the performance degradation threshold, set the gate electrode, the source electrode and the substrate of the transistor to be repaired to a low level and set the drain electrode of the transistor to be repaired to a high level to trigger a gate-induced drain leakage current according to the repair parameter; and in the case that the current performance degradation ratio is less than the performance degradation threshold, determine the second pre-failure duration according to the third performance-related parameter and the performance degradation-related parameter; after timing of the timer reaches the second pre-failure duration, set the gate electrode, the source electrode and the substrate of the transistor to be repaired to a low level and set the drain electrode of the transistor to be repaired to a high level to trigger a gate-induced drain leakage current according to the repair parameter; and update the first pre-failure duration according to the second pre-failure duration.

When the above-mentioned solution is adopted, the beneficial effects of the implementation solution may be referred to the relevant description of the beneficial effects corresponding to “ . . . after timing reaches the first pre-failure duration, . . . , and repeatedly performing the operation” in the preceding description, which will not be repeated here.

### BRIEF DESCRIPTION OF THE DRAWINGS

The accompanying drawings are used to provide further understanding of the present disclosure and form a part of the present disclosure. Exemplary embodiments of the present disclosure and the descriptions thereof are used to explain the present disclosure and do not constitute an improper limitation to the present disclosure. In the accompanying drawings:

FIG. 1 shows a flowchart of a method of repairing an integrated circuit provided in an embodiment of the present disclosure;

FIG. 2 shows a flowchart of an implementation solution of using a gate-induced drain leakage current repair method in an embodiment of the present disclosure; and

FIG. 3 shows a flowchart of another implementation solution of using a gate-induced drain leakage current repair method in an embodiment of the present disclosure.

### DETAILED DESCRIPTION OF EMBODIMENTS

In order to make technical problems to be solved, technical solutions and beneficial effects of embodiments of the present disclosure clearer, embodiments of the present disclosure will be further described in detail below with reference to the accompanying drawings and specific embodiments. It should be understood that the specific embodiments described here are merely used to explain the embodiments of the present disclosure and are not used to limit the embodiments of the present disclosure.

It should be noted that when an element is referred to as being “fixed to” or “disposed on” another element, it may be located directly on the another element or indirectly on the another element. When an element is referred to as being “connected to” another element, it may be directly connected to the another element or indirectly connected to the another element.

In addition, the terms “first”, “second”, etc. are merely used for descriptive purposes and should not be understood as indicating or implying relative importance or implicitly indicating the number of technical features indicated. Thus, a feature defined with “first” or “second” may explicitly or implicitly include one or more such features. In the description of the embodiments of the present disclosure, “plurality of” means two or more, unless otherwise specifically defined, and “at least one” means one or more, unless otherwise specifically defined.

In the description of the embodiments of the present disclosure, it should be understood that the terms “upper”, “lower”, “front”, “rear”, “left”, “right”, etc. are used to indicate orientations or positional relationships shown based on the accompanying drawings, which are merely intended to facilitate the description of the present disclosure and simplify the description, and not to indicate or imply that the device or element referred to must have a specific orientation or must be constructed and operated in a specific orientation, and thus should not be understood as limitations to the embodiments of the present disclosure.

In the description of the embodiments of the present disclosure, it should be noted that unless otherwise clearly specified and limited, the terms “installed”, “interconnected” and “connected” should be understood in a broad sense. For example, it may refer to a fixed connection, a detachable connection, or an integral connection; it may refer to a mechanical connection or an electrical connection; it may refer to a direct connection or an indirect connection through an intermediate medium, and it may refer to an internal communication of two elements or an interaction relationship between two elements. For those ordinary skilled in the art, the specific meanings of the above-mentioned terms in the embodiments of the present disclosure may be understood according to specific situations.

An objective of the embodiments of the present disclosure is to provide a method of repairing an integrated circuit, which is used to improve a real-time performance and speed of an aging-related design of the integrated circuit, thereby enhancing a performance of an integrated circuit to be repaired during a long-term operation.

An integrated circuit may degrade in performance after a long-term operation, and thus fail to operate properly within a designed lifespan. In an overall design of an integrated circuit, it is needed to perform an optimization design in combination with post-production testing in order to extend the lifespan of the integrated circuit.

In the related art, to repair aging of an integrated circuit, it is typically to perform a lifespan test on the integrated circuit after a manufacture is completed, determine a failure cause of the integrated circuit through statistics in combination with aging situations of integrated circuits during actual applications after applying the integrated circuit, and then optimize device parameters and structural parameters of the integrated circuit to extend the lifespan. Such a repair method requires to adjust parameters through an actual lifespan testing in combination with the actual aging situation after production, which is a redesign of the integrated circuit, rather than a direct modification or repair of the integrated circuit that has been designed and produced. During a process of testing and modifying parameters, a large amount of time is consumed and a large number of integrated circuits with short lifespans are produced, resulting in low repair efficiency and lacking real-time performance. Furthermore, due to various limitations of the parameter adjustment method, it is difficult to accurately and effectively extend the lifespan of the integrated circuit, thus affecting the performance of the integrated circuit during a long-term operation.

In addition, in the related art, when designing an integrated circuit, a Simulation Program with Integrated Circuit Emphasis (SPICE) model may be used to adjust parameters. However, the SPICE model generally lacks a circuit aging model or only has an imperfect circuit aging model, and it is still required to achieve an aging-related design through the above-mentioned post-production testing and statistical methods, which still has the same defects and is difficult to effectively repair the integrated circuit.

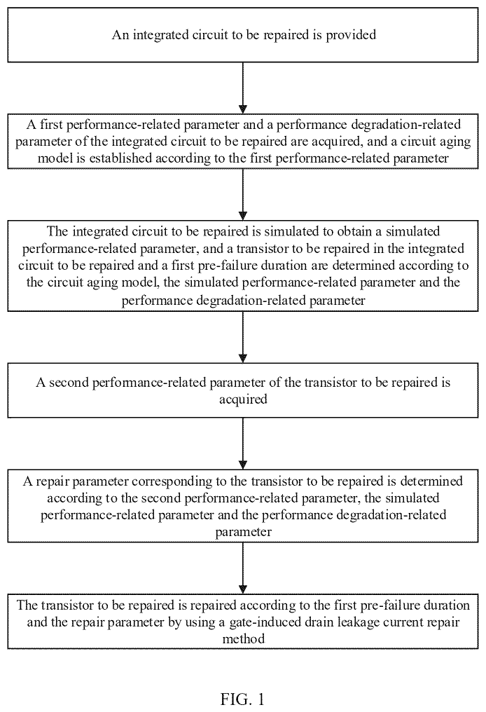

In order to improve the efficiency, real-time performance, repair accuracy and repair effect of the method of repairing the aging of the integrated circuit so as to enhance the performance of the integrated circuit to be repaired during a long-term operation, as shown in FIG. 1, an embodiment of the present disclosure provides a method of repairing an integrated circuit. The method of repairing the integrated circuit includes the following steps. First, an integrated circuit to be repaired is provided. Then, a first performance-related parameter and a performance degradation-related parameter of the integrated circuit to be repaired are acquired, and a circuit aging model is established according to the first performance-related parameter. Then, the integrated circuit to be repaired is simulated according to the circuit aging model to obtain a simulated performance-related parameter, and a transistor to be repaired in the integrated circuit to be repaired is determined according to the simulated performance-related parameter and the performance degradation-related parameter. Then, a second performance-related parameter of the transistor to be repaired is acquired. Next, a first pre-failure duration and a repair parameter for the transistor to be repaired are determined according to the second performance-related parameter, the simulated performance-related parameter and the performance degradation-related parameter. Then, the transistor to be repaired is repaired according to the first pre-failure duration and the repair parameter by using a gate-induced drain leakage current repair method.

When the above-mentioned technical solution is adopted, before repairing the integrated circuit to be repaired, the first performance-related parameter and the performance degradation-related parameter of the integrated circuit to be repaired are acquired in advance. The first performance-related parameter may characterize an operating state of the integrated circuit to be repaired and corresponding operating parameters in the operating state. Based on this, a circuit aging model for a single transistor included in the integrated circuit to be repaired is established according to the first performance-related parameter, so as to perform a targeted assessment of the aging situation of the integrated circuit to be repaired, thus accurately understanding the performance degradation situation of each transistor in the integrated circuit to be repaired and improving a simulation accuracy. In addition, the performance degradation-related parameter may be used as a determination threshold criterion for the integrated circuit to be repaired. Then, the obtained simulated performance-related parameter, that is, a simulation result, is compared with the performance degradation-related parameter to determine the aging situation and the first pre-failure duration of each transistor in the integrated circuit to be repaired. If the simulated performance-related parameter of a particular transistor meets a degradation criterion in the performance degradation-related parameter, that transistor may be determined as a transistor to be repaired, and the transistor to be repaired may be repaired in a subsequent repair process. Secondly, the ratio between the simulated performance-related parameter and the degradation-related parameter is used as a parameter to evaluate the degradation situation of the transistor to be repaired, so as to facilitate subsequent repair of the transistor to be repaired. The first pre-failure duration refers to a duration after which the simulated performance-related parameter of the transistor to be repaired is considered to meet the degradation criterion in the performance degradation-related parameter. After that, the second performance-related parameter of the transistor to be repaired is acquired, which serves as a basic device parameter of the transistor to be repaired and will be used as a basis for determining the specific means of the subsequent repair method. Then, the degradation situation of the transistor to be repaired is obtained according to the second performance-related parameter, the simulated performance-related parameter and the performance degradation-related parameter. Combining the degradation situation of the transistor to be repaired and the basic device parameter of the transistor to be repaired, the repair parameter for repairing the transistor to be repaired may be determined. Finally, the transistor to be repaired may be repaired according to the first pre-failure duration and the repair parameter by using a gate-induced drain leakage current repair method. In contrast to the related art, which relies on thermal annealing to repair an aged transistor to be repaired and requires annealing the entire integrated circuit to be repaired, thereby inevitably interrupting a normal operation of a system using the integrated circuit to be repaired and incurring lengthy repair time, the present disclosure is to repair the transistor to be repaired by using a gate-induced drain leakage current repair method, so that the integrated circuit to be repaired may be repaired without interrupting a normal operation of the system using the integrated circuit to be repaired, and the repair time may be significantly reduced. Moreover, the repair method provided in the present disclosure does not involve adjusting the device parameter of the integrated circuit and then remanufacturing the integrated circuit, thus solving the problems of low efficiency and low real-time performance of the indirect repair method in the related art that requires post-production testing of the integrated circuit to adjust the parameter of the integrated circuit for lifespan extension. Furthermore, by directly repairing the transistor to be repaired, it is possible to use relatively conservative repair parameters to solve the problems of low repair accuracy and poor repair effect caused by low simulation precision, thereby improving the performance of the integrated circuit to be repaired during a long-term operation.

In an actual application process, a type of the integrated circuit to be repaired is not specifically limited in embodiments of the present disclosure, as long as the performance degradation may be repaired using the gate-induced drain leakage current repair method. For example, the integrated circuit to be repaired may be a memory, an arithmetic unit, an amplifier, or other possible types.

Then, the first performance-related parameter and the performance degradation-related parameter of the integrated circuit to be repaired are acquired, and a circuit aging model is established according to the first performance-related parameter.

The first performance-related parameter is used to characterize the operating state of the integrated circuit to be repaired and the corresponding operating parameter in the operating state, which may effectively support the establishment of the circuit aging model. A specific parameter type of the first performance-related parameter may be determined according to the type of the integrated circuit and the actual application scenario, which is not limited in embodiments of the present disclosure.

Exemplarily, the first performance-related parameter may include a designed operating temperature, a designed maximum voltage stress, a designed operating duration, a designed threshold voltage, a designed saturation drain current, and a designed circuit turn-on delay time. In this case, the designed threshold voltage, the designed saturation drain current and the designed circuit turn-on delay time may comprehensively characterize various parameters required for the integrated circuit to be repaired in the operating state, so that the circuit aging model established based on the first performance-related parameter may accurately characterize the actual situation of the integrated circuit to be repaired and improve the accuracy of the simulation result, thereby improving the repair effect of the repair method provided in embodiments of the present disclosure.

The designed threshold voltage, the designed saturation drain current and the designed circuit turn-on delay time may be calculated from the design parameters of the integrated circuit to be repaired, or may be measured, for example, by using an oscilloscope.

The designed operating temperature, the designed maximum voltage stress and the designed operating duration are design values of the integrated circuit to be repaired. The integrated circuit to be repaired is required to maintain the designed threshold voltage, the designed saturation drain current and the designed circuit turn-on delay time within a degradation range specified by the performance degradation-related parameter after operating at the designed operating temperature under the designed maximum voltage stress for at least the designed operating duration.

In embodiments of the present disclosure, the relational expression of the circuit aging model is not limited to a relational expression of threshold voltage, but may further include a relational expression of saturation drain current and a relational expression of turn-on delay time. For example, when the relational expression of the circuit aging model is a relational expression of threshold voltage, the relational expression is:

$${V}_{th} = A * {e}^{\frac{- 1}{kT}} * {V}_{g} * b * {t}^{n} ,$$

where Vₜₕ represents a threshold voltage, A represents a first threshold voltage degradation parameter, k represents the Boltzmann constant, T represents an operating temperature, V_{g} represents a stress bias voltage, b represents a second threshold voltage degradation parameter, t represents an operating duration, and n is a time exponent.

When the above-mentioned solution is adopted, establishing the circuit aging model is to determine a specific value of the parameter. In this case, the threshold voltage in the circuit aging model may effectively characterize the aging situation of the integrated circuit to be repaired by using the above relational expression, making the circuit aging model more accurate and improving the repair effect of the repair method provided in embodiments of the present disclosure.

Further, in an embodiment, the specific method of establishing the circuit aging model according to the first performance-related parameter including the designed operating temperature, the designed operating duration, the designed threshold voltage, the designed saturation drain current and the designed circuit turn-on delay time may include: performing continuous testing on a single transistor in the integrated circuit by applying the designed maximum voltage stress to the single transistor at different temperatures included in the designed operating temperature; measuring specific values of the threshold voltage, the saturation drain current and the circuit turn-on delay time of the transistor after a plurality of different testing times; then based on these specific values, fitting a relationship between the threshold voltage, the saturation drain current, the turn-on delay time of the integrated circuit to be repaired and the operating duration, the operating temperature of the integrated circuit to be repaired to the above-mentioned relational expression through statistical software, so as to obtain the specific values in the relational expression.

It should be noted that the methods of determining other relational expressions of the circuit aging model are substantially the same as the method of determining the relational expression of the threshold voltage and its parameters, which will not be repeated here.

The performance degradation-related parameter is used as the criterion for determining the aging situation of the integrated circuit to be repaired. The specific parameter type of the performance degradation-related parameter may be determined according to the type of the integrated circuit and the parameter type required by the gate-induced drain leakage current repair method used, which is not limited in embodiments of the present disclosure.

Exemplarily, the performance degradation-related parameter includes: a circuit type, a degraded threshold voltage, a degraded saturation drain current, and a degraded circuit turn-on delay time. The circuit type includes a memory, an arithmetic unit, or an amplifier.

When the above-mentioned technical solution is adopted, the performance degradation-related parameter is used as the criterion for determining the aging situation of the integrated circuit to be repaired. The criterion for determining the aging situation of the integrated circuit to be repaired based on the four parameters including the circuit type, the degraded threshold voltage, the degraded saturation drain current and the degraded circuit turn-on delay time may comprehensively characterize various parameters required for the integrated circuit to be repaired in the operating state, so that a result of determining the integrated circuit to be repaired using the performance degradation-related parameter is more effective, the transistor to be repaired may be determined accurately, and the accuracy of the simulation result may be improved, thereby improving the repair effect of the repair method provided in embodiments of the present disclosure.

Specifically, regarding a range of the performance degradation-related parameter, when the integrated circuit to be repaired is a memory, a difference between the degraded threshold voltage and the designed threshold voltage is greater than or equal to 30 mV, a degradation ratio between the degraded saturation drain current and the designed saturation drain current is greater than or equal to 15%, and a degradation ratio between the designed circuit turn-on delay time and the degraded circuit turn-on delay time is greater than or equal to 30%.

When the integrated circuit to be repaired is an arithmetic unit, a difference between the degraded threshold voltage and the designed threshold voltage is greater than or equal to 30 mV, a degradation ratio between the degraded saturation drain current and the designed saturation drain current is greater than or equal to 15%, and a degradation ratio between the designed circuit turn-on delay time and the degraded circuit turn-on delay time is greater than or equal to 30%.

When the integrated circuit to be repaired is an amplifier, a difference between the degraded threshold voltage and the designed threshold voltage is greater than or equal to 30 mV, a degradation ratio between the degraded saturation drain current and the designed saturation drain current is greater than or equal to 15%, and a degradation ratio between the designed circuit turn-on delay time and the degraded circuit turn-on delay time is greater than or equal to 30%.

When the above-mentioned technical solution is adopted, since different types of integrated circuits to be repaired have different uses and may have the same or different failure criteria for different parameters, appropriate failure criteria are selected for different parameters according to operating characteristics of different types of integrated circuits to be repaired, thereby improving pertinence of the repair method provided in the present disclosure and ultimately improving the effect of the method of repairing the integrated circuit provided in the present disclosure.

Exemplarily, different types of integrated circuits to be repaired may have different failure criteria for different parameters. For example, if the integrated circuit to be repaired is a memory, which is relatively less sensitive to the degradation of device parameter, it is possible to select a looser failure criterion than when the integrated circuit to be repaired is an arithmetic unit. For example, the difference between the degraded threshold voltage and the designed threshold voltage is greater than or equal to 35 mV, the degradation ratio between the degraded saturation drain current and the designed saturation drain current is greater than or equal to 17%, and the degradation ratio between the designed circuit turn-on delay time and the degraded circuit turn-on delay time is greater than or equal to 35%. If the integrated circuit to be repaired is an amplifier, which is more sensitive to the degradation of device parameter than the arithmetic unit, it is possible to select a stricter failure criterion. For example, the difference between the degraded threshold voltage and the designed threshold voltage is greater than or equal to 25 mV, the degradation ratio between the degraded saturation drain current and the designed saturation drain current is greater than or equal to 10%, and the degradation ratio between the designed circuit turn-on delay time and the degraded circuit turn-on delay time is greater than or equal to 25%.

Then, the integrated circuit to be repaired is simulated according to the circuit aging model to obtain a simulated performance-related parameter; and the transistor to be repaired in the integrated circuit to be repaired and the first pre-failure duration are determined according to the circuit aging model, the simulated performance-related parameter, and the performance degradation-related parameter.

Exemplarily, a duration after which the simulated performance-related parameter of any integrated circuit to be repaired exceeds the performance degradation-related parameter may be calculated according to the relational expression of the circuit aging model, and the duration is recorded as a pre-failure operating duration t0. Then, a device simulation for each transistor in the integrated circuit to be repaired is performed using integrated circuit simulation software including Cadence, ANSYS and Empyrean, so as to obtain an operating cycle duration T1 of the integrated circuit to be repaired and a duration t that each transistor withstands voltage stress in one operating cycle. The operating cycle refers to a minimum cycle of a repetitive operation of the integrated circuit to be repaired in an actual operating process. Then, it is possible to divide the designed operating duration by T1 to obtain a designed number of operating cycle N. Then, a transistor with t greater than or equal to t0/N may be selected and set as the transistor to be repaired.

Then, the first pre-failure duration is determined according to the pre-failure operating duration t0 and the actual situation. When subsequently repairing the transistor to be repaired, a cumulative time that the transistor to be repaired withstands the voltage stress is counted and compared with the first pre-failure duration. In the above-mentioned implementation solution, the first pre-failure duration may be the pre-failure operating duration t0, or the first pre-failure duration may be shorter or longer than the pre-failure operating duration to, which may be determined according to the actual manufacturing situation of the integrated circuit to be repaired. Specifically, if it is desired to provide an early warning for the aging of the transistor to be repaired and perform a conservative repair method, the first pre-failure duration may be short, and may be significantly shorter than the pre-failure operating duration t0. Furthermore, the device simulation of the circuit aging model is merely a theoretical simulation. In the actual application process, it is possible to combine the post-production actual device parameter, actual operating environment, operating conditions and other parameters of the integrated circuit to be repaired with the pre-failure operating duration t0 to adjust the specific value of the first pre-failure duration based on a failure warning time, so as to improve the repair precision and repair accuracy of the repair method provided in embodiments of the present disclosure. For example, in a case of a perfect manufacturing process and a high yield of the integrated circuit to be repaired, the first pre-failure duration may be appropriately extended compared to the pre-failure operating duration t0, so as to reduce the number of repairs and reduce a secondary damage caused by repairs, and thus further extend the lifespan of the integrated circuit to be repaired. In a case of an imperfect manufacturing process and a low yield of the integrated circuit to be repaired, the first pre-failure duration may be appropriately shortened compared to the pre-failure operating duration t0, so as to further ensure the lifespan of the integrated circuit to be repaired.

Exemplarily, a value range of the first pre-failure duration may be greater than or equal to 80% of the pre-failure operating duration t0 and less than or equal to 110% of the pre-failure operating duration to.

The simulated performance-related parameter is used as a simulation result of the circuit aging model. The simulated performance-related parameter has the same parameter type as the performance degradation-related parameter. By comparing the simulated performance-related parameter with the performance degradation-related parameter, the aging situation of the integrated circuit to be repaired and the transistor to be repaired in the integrated circuit to be repaired may be determined more effectively.

Exemplarily, the simulated performance-related parameter includes a circuit type, a simulated threshold voltage, a simulated saturation drain current, and a simulated circuit turn-on delay time.

Then, a second performance-related parameter of the transistor to be repaired is acquired. The second performance-related parameter is used as a device parameter of the transistor to be repaired. In subsequent repair of the transistor to be repaired, the second performance-related parameter is used to repair the device aging of the transistor to be repaired. To achieve a better repair effect, different transistors to be repaired need to have different second performance-related parameters to achieve a better repair effect.

Exemplarily, the second performance-related parameter includes a decrease amount of threshold voltage, a subthreshold swing, a transconductance, an electric field strength distribution, a decrease amount of saturation drain current, an overlapping length between gate region and drain region, and a gate dielectric layer thickness.

When the above-mentioned solution is adopted, common device aging, such as hot carrier degradation (HCD), originates from heating and subsequent carrier injection into a gate oxide layer, which leads to a formation of local and non-uniform interface states and oxide charge accumulation near a drain junction of the transistor. The resulting defects may cause threshold voltage drift, transconductance degradation, drain current reduction, etc., ultimately causing device failure. Furthermore, a lateral electric field near the drain junction causes carrier heating and avalanche, the lateral electric field affects the carrier injection into the gate oxide layer, and the electric field distribution in the transistor may also have a significant impact on the hot carrier degradation of the transistor. In this case, specific parameters such as the decrease amount of threshold voltage, the subthreshold swing, the transconductance, the electric field strength distribution, the decrease amount of saturation drain current, the overlapping length between gate region and drain region, and the gate dielectric layer thickness used as device parameters of the transistor to be repaired may effectively represent the hot carrier degradation of the transistor to be repaired, thereby facilitating the subsequent accurate calculation of the first pre-failure duration and the repair parameter, and improving the repair effect of the repair method provided in embodiments of the present disclosure.

Then, a repair parameter for the transistor to be repaired is determined according to the second performance-related parameter, the simulated performance-related parameter and the performance degradation-related parameter. Specifically, a gate-drain voltage and a repair time in the repair parameter are determined according to the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter, so as to ensure that the subsequent repair of the transistor to be repaired is effective.

The repair parameter is used as an operating parameter for subsequent repair. Since a gate-induced drain leakage current repair method is adopted for repair in the repair method provided in embodiments of the present disclosure, obtaining the gate-drain voltage and the repair time used for the repair may further improve the repair effect and ensure that the repair effect meets the design expectations.

Optionally, the gate-drain voltage is determined according to at least one of the overlapping length between gate region and drain region or the gate dielectric layer thickness of the transistor to be repaired, and the repair time is determined according to a degradation situation of the transistor to be repaired.

When the above-mentioned solution is adopted, the gate-drain voltage and the repair time in the repair parameter are obtained by combining and analyzing the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter, and they are used to repair the transistor to be repaired. Based on the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter, the gate-drain voltage and the repair time used for repairing the transistor to be repaired may be accurately determined, thereby improving the repair effect of the method of repairing the integrated circuit provided in embodiments of the present disclosure.

Then, the transistor to be repaired is repaired according to the first pre-failure duration and the repair parameter by using a gate-induced drain leakage current repair method.

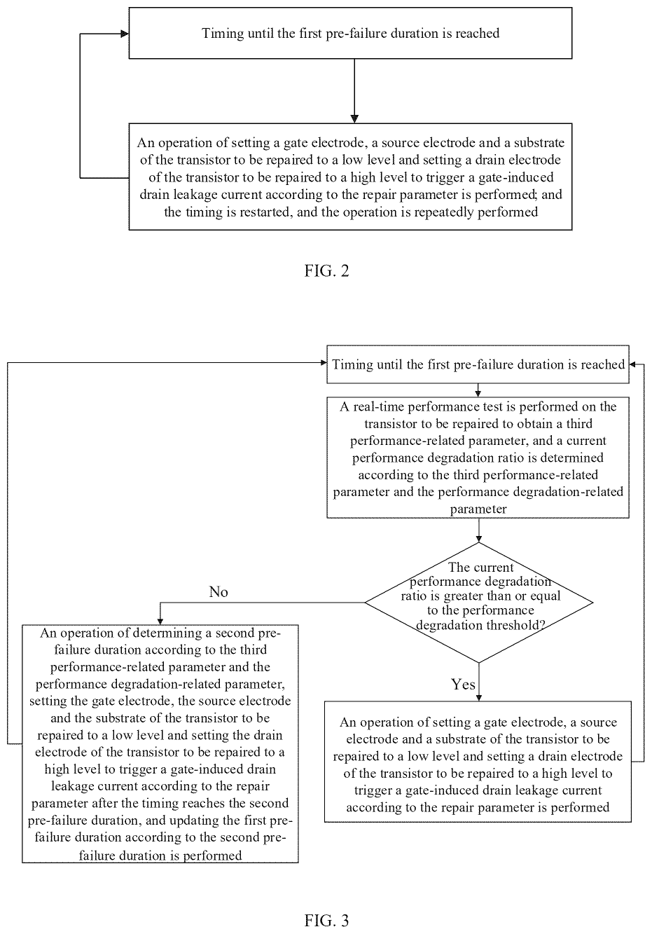

The method of repairing the transistor to be repaired according to the first pre-failure duration and the repair parameter by using the gate-induced drain leakage current repair method is not limited in embodiments of the present disclosure, which may be determined according to, for example, actual design requirements for lifespan and power consumption. Exemplarily, referring to FIG. 2 and FIG. 3, two possible implementation solutions are provided for the method of repairing the integrated circuit in embodiments of the present disclosure.

As a possible implementation solution, referring to FIG. 2, repairing the transistor to be repaired according to the first pre-failure duration and the repair parameter by using a gate-induced drain leakage current repair method includes: performing an operation of setting a gate electrode, a source electrode and a substrate of the transistor to be repaired to a low level and setting a drain electrode of the transistor to be repaired to a high level to trigger a gate-induced drain leakage current according to the repair parameter after timing reaches the first pre-failure duration; and restarting the timing, and repeatedly performing the operation.

When the above-mentioned solution is adopted, after the timing reaches the first pre-failure duration, the transistor to be repaired is repaired using a gate-induced drain leakage current repair method. The repair method is simple, and the corresponding repair circuit is also simple, which may reduce a design difficulty of the method of repairing the integrated circuit provided in embodiments of the present disclosure and reduce the design overhead and power consumption overhead on the repair circuit.

As another possible implementation solution, referring to FIG. 3, repairing the transistor to be repaired according to the first pre-failure duration and the repair parameter by using a gate-induced drain leakage current repair method includes: performing an operation of: performing a real-time performance test on the transistor to be repaired to obtain a third performance-related parameter after timing reaches the first pre-failure duration, and determining a current performance degradation ratio according to the third performance-related parameter and the performance degradation-related parameter; in a case that the current performance degradation ratio is greater than or equal to a performance degradation threshold, setting a gate electrode, a source electrode and a substrate of the transistor to be repaired to a low level and setting a drain electrode of the transistor to be repaired to a high level to trigger a gate-induced drain leakage current according to the repair parameter; and in a case that the current performance degradation ratio is less than the performance degradation threshold, determining a second pre-failure duration according to the third performance-related parameter and the performance degradation-related parameter; after the timing reaches the second pre-failure duration, setting the gate electrode, the source electrode and the substrate of the transistor to be repaired to a low level and setting the drain electrode of the transistor to be repaired to a high level to trigger a gate-induced drain leakage current according to the repair parameter; and updating the first pre-failure duration according to the second pre-failure duration; and restarting the timing and repeatedly performing the operation.

When the above-mentioned solution is adopted, the second pre-failure duration and the first pre-failure duration have the same starting time; and the performance degradation threshold may be obtained manually according to actual needs, or may be a threshold of the difference between the degraded threshold voltage and the designed threshold voltage, a threshold of the degradation ratio between the degraded saturation drain current and the designed saturation drain current, and a threshold of the degradation ratio between the designed circuit turn-on delay time and the degraded circuit turn-on delay time included in the performance degradation-related parameter. The third performance-related parameter includes the threshold voltage, the saturation drain current and the circuit turn-on delay time of the transistor to be repaired. Determining the current performance degradation ratio according to the third performance-related parameter and the performance degradation-related parameter is to determine the current performance degradation ratio of the threshold voltage, saturation drain current and circuit turn-on delay time of the transistor to be repaired, and determine whether the current performance degradation ratio exceeds the above-mentioned performance degradation threshold included in the performance degradation-related parameter. In this case, embodiments of the present disclosure provide another repair method, which expands an application scope of the method of repairing the integrated circuit provided in embodiments of the present disclosure. Furthermore, since a real-time performance test is performed on the transistor to be repaired and a third performance-related parameter is obtained before the transistor to be repaired is repaired, and then the current performance degradation ratio is determined according to the third performance-related parameter and the performance degradation-related parameter, the transistor to be repaired may be repaired only when the current performance degradation ratio is greater than or equal to the performance degradation threshold, thereby reducing the number of repairs, avoiding invalid repairs or multiple repairs that may damage the device structure of the transistor to be repaired, and effectively extending the lifespan of the integrated circuit to be repaired.

When specifically applying the method of repairing the integrated circuit provided in embodiments of the present disclosure, a repair circuit is typically used to repair the transistor to be repaired according to the first pre-failure duration and the repair parameter. Structures of the repair circuit corresponding to the above-mentioned implementation solutions and specific functions corresponding to the structures are not limited in embodiments of the present disclosure, which may be determined according to, for example, actual requirements for power consumption of the repair structure.

Exemplarily, the repair circuit includes a timer and a repair module. The timer is configured to be triggered at intervals of the first pre-failure duration, and the repair module is connected to at least the gate electrode, the source electrode, the drain electrode and the substrate of the transistor to be repaired. The repair module may be used to: test a performance of the transistor to be repaired to obtain the third performance-related parameter after the timer is triggered, and determine the current performance degradation ratio according to the third performance-related parameter and the performance degradation-related parameter; in the case that the current performance degradation ratio is greater than or equal to the performance degradation threshold, set the gate electrode, the source electrode and the substrate of the transistor to be repaired to a low level and set the drain electrode of the transistor to be repaired to a high level to trigger a gate-induced drain leakage current according to the repair parameter; and in the case that the current performance degradation ratio is less than the performance degradation threshold, determine the second pre-failure duration according to the third performance-related parameter and the performance degradation-related parameter; after timing of the timer reaches the second pre-failure duration, set the gate electrode, the source electrode and the substrate of the transistor to be repaired to a low level and set the drain electrode of the transistor to be repaired to a high level to trigger a gate-induced drain leakage current according to the repair parameter; and update the first pre-failure duration according to the second pre-failure duration.

It should be noted that a voltage difference between the high level and the low level may be determined by the repair parameter.

A specific type of the timer may be determined according to the actual application scenario. For example, the timer may be a built-in timer of a single-chip microcomputer for timing, and the first pre-failure duration is stored in a built-in memory of the single-chip microcomputer.

A specific structure of the repair module may be determined according to the actual application scenario. For example, the repair module may include a single-chip microcomputer, a digital-to-analog converter, and repair circuits connected to the gate electrode, the source electrode, the drain electrode and the substrate of the transistor to be repaired. The built-in memory of the single-chip microcomputer may store the repair parameter, the performance degradation-related parameter, a program for collecting the third performance-related parameter, and a program for determining the current performance degradation ratio and calculating the second pre-failure duration.

When the above-mentioned solution is adopted, the beneficial effects of the implementation solution may be referred to the relevant description of the above-mentioned another possible implementation solution, which will not be repeated here.

In the description of the above-mentioned implementation solutions, specific features, structures, materials or characteristics may be combined in any one or more embodiments or examples in a suitable manner.

The above are merely specific implementations of embodiments of the present disclosure, and the protection scope of embodiments of the present disclosure is not limited thereto. Any changes or substitutions that those skilled in the art may easily conceive of within the technical scope revealed in embodiments of the present disclosure should be contained within the protection scope of embodiments of the present disclosure. Therefore, the protection scope of embodiments of the present disclosure should be determined by the protection scope of the claims.

What is claimed is:

1. A method of repairing an integrated circuit, comprising:
providing an integrated circuit to be repaired;
acquiring a first performance-related parameter and a performance degradation-related parameter of the integrated circuit to be repaired, and establishing a circuit aging model according to the first performance-related parameter;
simulating the integrated circuit to be repaired to obtain a simulated performance-related parameter, and determining a transistor to be repaired in the integrated circuit to be repaired and a first pre-failure duration according to the circuit aging model, the simulated performance-related parameter and the performance degradation-related parameter;
acquiring a second performance-related parameter of the transistor to be repaired;
determining a repair parameter corresponding to the transistor to be repaired according to the second performance-related parameter, the simulated performance-related parameter and the performance degradation-related parameter; and
repairing the transistor to be repaired according to the first pre-failure duration and the repair parameter by using a gate-induced drain leakage current repair method.

2. The method of repairing the integrated circuit according to claim 1, wherein the first performance-related parameter comprises a designed operating temperature, a designed maximum voltage stress, a designed operating duration, a designed threshold voltage, a designed saturation drain current, and a designed circuit turn-on delay time; and/or
wherein the performance degradation-related parameter comprises a circuit type, a degraded threshold voltage, a degraded saturation drain current, and a degraded circuit turn-on delay time, and the circuit type comprises a memory, an arithmetic unit, or an amplifier.

3. The method of repairing the integrated circuit according to claim 2, wherein in a case that the integrated circuit to be repaired is the memory, a difference between the degraded threshold voltage and the designed threshold voltage is greater than or equal to 30 mV, a degradation ratio between the degraded saturation drain current and the designed saturation drain current is greater than or equal to 15%, and a degradation ratio between the designed circuit turn-on delay time and the degraded circuit turn-on delay time is greater than or equal to 30%;
wherein in a case that the integrated circuit to be repaired is the arithmetic unit, a difference between the degraded threshold voltage and the designed threshold voltage is greater than or equal to 30 mV, a degradation ratio between the degraded saturation drain current and the designed saturation drain current is greater than or equal to 15%, and a degradation ratio between the designed circuit turn-on delay time and the degraded circuit turn-on delay time is greater than or equal to 30%; or
wherein in a case that the integrated circuit to be repaired is the amplifier, a difference between the degraded threshold voltage and the designed threshold voltage is greater than or equal to 30 mV, a degradation ratio between the degraded saturation drain current and the designed saturation drain current is greater than or equal to 15%, and a degradation ratio between the designed circuit turn-on delay time and the degraded circuit turn-on delay time is greater than or equal to 30%.

4. The method of repairing the integrated circuit according to claim 1, wherein the second performance-related parameter comprises a decrease amount of threshold voltage, a subthreshold swing, a transconductance, an electric field strength distribution, a decrease amount of saturation drain current, an overlapping length between gate region and drain region, and a gate dielectric layer thickness.

5. The method of repairing the integrated circuit according to claim 1, wherein a relational expression of the circuit aging model comprises:
$${V}_{th} = A * {e}^{\frac{- 1}{kT}} * {V}_{g} * b * {t}^{n}$$
where Vₜₕ represents a threshold voltage, A represents a first threshold voltage degradation parameter, k represents the Boltzmann constant, T represents an operating temperature, V_{g} represents a stress bias voltage, b represents a second threshold voltage degradation parameter, t represents an operating duration, and n is a time exponent; and/or
wherein the determining a transistor to be repaired in the integrated circuit to be repaired and a first pre-failure duration according to the circuit aging model, the simulated performance-related parameter and the performance degradation-related parameter comprises:
calculating the first pre-failure duration according to the circuit aging model and the performance degradation-related parameter; and
determining the transistor to be repaired according to the first pre-failure duration and the simulated performance-related parameter.

6. The method of repairing the integrated circuit according to claim 4, wherein the simulated performance-related parameter comprises a circuit type, a simulated threshold voltage, a simulated saturation drain current, and a simulated circuit turn-on delay time; and
wherein the repair parameter comprises a gate-drain voltage and a repair time.

7. The method of repairing the integrated circuit according to claim 6, wherein the determining a repair parameter corresponding to the transistor to be repaired according to the second performance-related parameter, the simulated performance-related parameter and the performance degradation-related parameter comprises:
determining the gate-drain voltage and the repair time in the repair parameter according to the decrease amount of threshold voltage, the subthreshold swing, the transconductance, the electric field strength distribution, the decrease amount of saturation drain current, the overlapping length between gate region and drain region, and the gate dielectric layer thickness in the second performance-related parameter as well as the simulated threshold voltage, the simulated saturation drain current and the simulated circuit turn-on delay time in the simulated performance-related parameter.

8. The method of repairing the integrated circuit according to claim 1, wherein the repairing the transistor to be repaired according to the first pre-failure duration and the repair parameter by using a gate-induced drain leakage current repair method comprises:
performing an operation of setting a gate electrode, a source electrode and a substrate of the transistor to be repaired to a low level and setting a drain electrode of the transistor to be repaired to a high level to trigger a gate-induced drain leakage current according to the repair parameter after timing reaches the first pre-failure duration; and
restarting the timing, and repeatedly performing the operation.

9. The method of repairing the integrated circuit according to claim 1, wherein the repairing the transistor to be repaired according to the first pre-failure duration and the repair parameter by using a gate-induced drain leakage current repair method comprises:
performing an operation of:
performing a real-time performance test on the transistor to be repaired to obtain a third performance-related parameter after timing reaches the first pre-failure duration, and determining a current performance degradation ratio according to the third performance-related parameter and the performance degradation-related parameter;
in a case that the current performance degradation ratio is greater than or equal to a performance degradation threshold, setting a gate electrode, a source electrode and a substrate of the transistor to be repaired to a low level and setting a drain electrode of the transistor to be repaired to a high level to trigger a gate-induced drain leakage current according to the repair parameter; and
in a case that the current performance degradation ratio is less than the performance degradation threshold, determining a second pre-failure duration according to the third performance-related parameter and the performance degradation-related parameter; after the timing reaches the second pre-failure duration, setting the gate electrode, the source electrode and the substrate of the transistor to be repaired to a low level and setting the drain electrode of the transistor to be repaired to a high level to trigger a gate-induced drain leakage current according to the repair parameter; and updating the first pre-failure duration according to the second pre-failure duration; and
restarting the timing and repeatedly performing the operation.

10. The method of repairing the integrated circuit according to claim 9, wherein the repairing the transistor to be repaired according to the first pre-failure duration and the repair parameter by using a gate-induced drain leakage current repair method further comprises:
repairing, by using a repair circuit, the transistor to be repaired according to the first pre-failure duration and the repair parameter by using the gate-induced drain leakage current repair method, wherein the repair circuit comprises a timer and a repair module, the timer is configured to be triggered at intervals of the first pre-failure duration, and the repair module is connected to at least the gate electrode, the source electrode, the drain electrode and the substrate of the transistor to be repaired;
wherein the repair module is configured to:
test a performance of the transistor to be repaired to obtain the third performance-related parameter after the timer is triggered, and determine the current performance degradation ratio according to the third performance-related parameter and the performance degradation-related parameter;
in the case that the current performance degradation ratio is greater than or equal to the performance degradation threshold, set the gate electrode, the source electrode and the substrate of the transistor to be repaired to a low level and set the drain electrode of the transistor to be repaired to a high level to trigger a gate-induced drain leakage current according to the repair parameter; and
in the case that the current performance degradation ratio is less than the performance degradation threshold, determine the second pre-failure duration according to the third performance-related parameter and the performance degradation-related parameter; after timing of the timer reaches the second pre-failure duration, set the gate electrode, the source electrode and the substrate of the transistor to be repaired to a low level and set the drain electrode of the transistor to be repaired to a high level to trigger a gate-induced drain leakage current according to the repair parameter; and update the first pre-failure duration according to the second pre-failure duration.
